(19) United States
(12) Patent Application Publication
(10) Pub. No.: US 2003/0179547 A1
(43) Pub. Date: Sep. 25, 2003

(54) Switch housing with a cooling device

(76) Inventor: Achim Edelmann, Wilnsdorf (DE)

Correspondence Address: Pauley Petersen Kinne & Erickson, 2800 West Higgins Road Suite 365, Hoffman Estates, IL, 60195, US

(21) Appl. No.: 10/204,148

(22) PCT Filed: Feb. 9, 2001
(86) PCT No.: PCT/EP01/01437

(30) Foreign Application Priority Data
Feb. 18, 2000 (DE) 10007467.7

(51) Int. Cl. H05K 7/20

(52) U.S. Cl. 361/699

(57) ABSTRACT

The invention relates to a switch cupboard housing, comprising a cooling device which has a cooling circuit with a compressor and a condenser. The switch housing has an outer covering which at least partially surrounds an inner switch housing area in which a mounting plate is fixed. According to the invention, the mounting plate is configured in the form of a compressor to which a pipeline system guiding the coolant of the cooling circuit is allocated. The condenser forms at least one part of the outer covering and a pipeline system for the coolant is also allocated to said condenser. The cooling device is also configured without ventilators/fans. The invention hereby provides a cooling device with a simple construction that is easy to maintain.

The invention relates to a switch housing with a cooling device, which has a cooling circuit with an evaporator and a condenser, in which the switch housing has an outer covering, which at least partially surrounds a switch housing interior, and in which a mounting plate is secured in the switch housing interior.

Switch housings of this kind are known from the prior art. Electric or electronic assemblies on the mounting plate can be positioned in the switch housing interior. During operation, these components give off dissipated energy in the form of heat. The cooling device is used to prevent an impermissible overheating on the interior of the switch housing. It exchanges the heat quantity produced with the surroundings. These cooling devices typically require high maintenance expenditures since in particular, the fans used require regular testing and must be replaced when damaged.

The object of the invention is to produce a housing of the type mentioned at the beginning in which the cooling device is embodied so that it is simple in design and is simultaneously easy to maintain.

This object is attained in that the mounting plate is embodied as an evaporator, which is associated with a conduit system in which the cooling medium of the cooling circuit is conveyed, that the condenser constitutes at least part of the outer covering and is likewise associated with a conduit system for the cooling medium, and that the cooling device is embodied without ventilators or fans.

In this embodiment, the electric or electronic components are fastened to the mounting plate. They transmit the dissipated energy directly into the cooled mounting plate, which is embodied as the evaporator. The dissipated energy is then transported away with the cooling medium conveyed in the conduit system and is supplied to the condenser. The condenser itself then exchanges the heat with the surroundings. This cooling device eliminates the use of high-maintenance fans.

A preferred embodiment of the invention provides that the condenser, the mounting plate, and a compressor are combined to form a mounting unit and are operatively connected to one another. The mounting unit can therefore be easily connected to an existing switch housing.

In order to prevent the dissipated heat from being transmitted from the condenser back into the switch housing interior, one embodiment of the invention provides that the condenser is backed by an insulation layer on its side oriented toward the switch housing interior.

In particular is also possible to provide that the condenser is embodied as plate-shaped and is secured parallel to and spaced apart from the mounting plate, and that the insulation layer is accommodated in the space between the mounting plate and the condenser and thermally decouples the condenser from the mounting plate.

A favorable, large-area heat exchange into the surroundings can take place if the condenser is comprised of a thermoconductive material that is cast into to the associated conduit system. The condenser can also have cooling ribs formed onto it and of one piece with it on its outside oriented toward the surroundings.

It is also conceivable if the mounting plate is comprised of a thermoconductive material into which the associated conduit system is cast. This permits a compact, uniformly usable unit. The use of this unit simplifies the assembly of the cooling device.

In order to achieve a favorable heat dissipation from the electric or electronic components, the invention provides that the mounting plate has a flat mounting surface, which is oriented toward the switch housing interior and is provided with fastening receptacles.

The invention will be described in detail below in conjunction with an exemplary embodiment shown in the drawings.

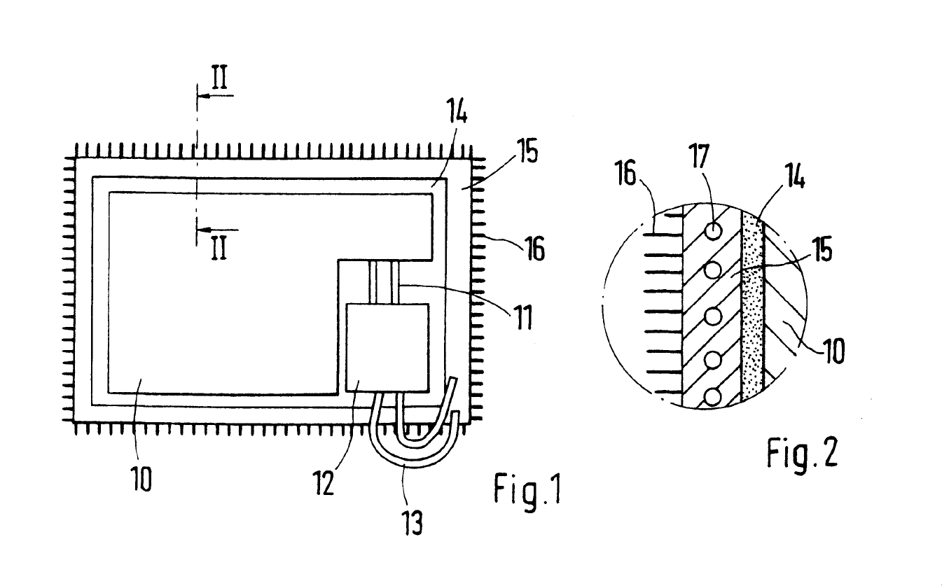

FIG. 1 shows a cooling device in a schematic, top view and

FIG. 2 shows an enlarged sectional view along the cutting line II-II indicated in FIG. 1.

FIG. 1 shows a cooling device, which is embodied as a preassembled unit. It has a cooling circuit with an evaporator 10 and a condenser 15. The evaporator 10 is embodied as a mounting plate and is provided with a grid of fastening receptacles spaced apart from one another in a uniform pattern. The fastening receptacles are not shown in FIG. 1. The evaporator is comprised of a favorably thermoconductive material, for example aluminum. A conduit system is cast into the mounting plate 10. This conduit system has a meandering course. The conduit system is connected to a compressor 12 by means of coolant lines 11. The compressor 12 is also associated with a regulating control unit, which continuously monitors and controls the functions of the cooling device. Coolant lines 13 lead from the compressor 12 and are connected to a conduit system of the condenser 15. The condenser 15 is embodied similarly to the mounting plate 10. The design of the condenser 15 is shown in more detail in FIG. 2.

As shown in this drawing, the conduit system 17 is cast into the material of the condenser 15. The material of the condenser 15 is favorably thermoconductive; for example, the condenser 15 is comprised of aluminum. On the outside oriented away from the mounting plate 10, cooling ribs 16 are formed onto and of one piece with the condenser 15. Like the mounting plate 10, the condenser 15 is embodied as plate-shaped. Between the mounting plate 10 and the condenser 15 there is an open space. This open space is filled with an insulation layer 14. The insulation layer 14 thermally decouples the condenser 15 from the mounting plate 10.

As shown in FIG. 1, in terms of its outer dimensions, the condenser 15 is embodied as larger than the insulation layer 14. This produces a continuous fastening flange. The cooling device can be inserted as a preassembled unit into an opening of an outer covering of a switch housing. The continuous flange is supported on the outside of the outer covering and can be connected to it, for example by means of screws. The insulation layer 14 completely fills the section of the outer covering into which the cooling device is mounted. This prevents a transmission of heat from the condenser 15 into the switch housing interior. When mounted in place, the condenser 15 is consequently secured to the outside and the mounting plate 10 is secured on the interior of the switch housing.

Electric or electronic components can be fastened to the mounting plate 10, oriented toward the interior of the switch housing. These components are in surface contact with the mounting plate 10. During the operation of the components, they transmit their dissipated energy in the form of heat to the mounting plate 10. Since the mounting plate 10 constitutes the evaporator of the cooling circuit, it is always kept at a low operating temperature, thus permitting an effective heat dissipation. The heat is transmitted into the conduit system and therefore into the cooling medium circulating in the cooling circuit. By means of the coolant lines 11, 13 the cooling medium can supply the heat to the condenser 15. This is where the heat exchange with the surroundings finally takes place. This can take place in an effective manner because a large heat exchanging surface area is produced by means of the cooling ribs 16.

1. A switch housing with a cooling device, which has a cooling circuit with an evaporator and a condenser (15), where the switch housing has an outer covering, which at least partially surrounds a switch housing interior, where a mounting plate (10) is secured in the switch housing interior, where the mounting plate (10) is embodied as an evaporator, which is associated with a conduit system in which the cooling medium of the cooling circuit is conveyed, where the plate-shaped condenser (15) constitutes at least part of the outer covering and is likewise associated with a conduit system (17) for the cooling medium, and where the cooling device is embodied without ventilators or fans, characterized in that the condenser (15), the mounting plate (10), and a compressor (12) are combined to form a mounting unit and are operatively connected to one another, that the condenser (15) is secured spaced apart from the mounting plate (10), and that the insulation layer (14) is accommodated in the space between the mounting plate (10) and the condenser (15) and thermally decouples the condenser (15) from the mounting plate (10).

2. The switch housing according to claim 1, characterized in that the condenser (15) is backed by an insulation layer (14) on its side oriented toward the switch housing interior.

3. The switch housing according to one of claims 1 or 2, characterized in that the condenser (15) is comprised of a thermoconductive material into which the associated conduit system (17) is cast.

4. The switch housing according to claim 3, characterized in that the condenser (15) has cooling ribs (16) formed onto it and of one piece with it on its outside oriented toward the surroundings.

5. The switch housing according to one of claims 1 to 4, characterized in that the mounting plate (10) is comprised of a thermoconductive material into which the associated conduit system is cast.

6. The switch housing according to one of claims 1 to 5, characterized in that the mounting plate (10) has a flat mounting surface, which is oriented toward the switch housing interior and is provided with fastening receptacles.
